(19) United States
(12) Patent Application Publication
(10) Pub. No.: US 2003/0084852 A1
(43) Pub. Date: May 8, 2003

(54) Temperature control elements, spindle assembly, and wafer processing assembly incorporating same

(76) Inventors: John T. Davlin, Nampa, ID (US); Greg Montanino, Mountain Home, ID (US)

Correspondence Address: Killworth, Gottman, Hagan & Schaeff, L.L.P., Suite 500, One Dayton Centre, Dayton, OH, 45402-2023, US

(21) Appl. No.: 10/320,073

(22) Filed: Dec. 16, 2002

Related U.S. Application Data
(62) Division of application No. 09/651,498, filed on Aug. 30, 2000.

(51) Int. Cl. C23F 1/00; C23C 16/00

(52) U.S. Cl. 118/730; 156/345.55

(57) ABSTRACT

The present invention relates to temperature control elements, spindle assemblies, and wafer processing assemblies. According to one embodiment of the present invention, a wafer processing assembly is provided comprising a rotary spindle assembly, at least one liquid source, a controller, a wafer support, and a wafer processing bowl. The rotary spindle assembly comprises a rotary drive motor, a rotary spindle coupled to the rotary drive motor, a heat regulating element arranged about the rotary spindle, and a heat regulating flange secured to the rotary drive motor. The controller is coupled to the liquid source and a temperature sensor coupled to one or both of the heat regulating element and the heat regulating flange and is programmed to be responsive to a temperature signal generated by the temperature sensor.

### CROSS REFERENCE TO RELATED APPLICATIONS

This application is a division of U.S. patent application Ser. No. 09/651,498, filed Aug. 30, 2000.

### BACKGROUND OF THE INVENTION

The present invention relates to wafer processing assemblies and wafer handling equipment wherein a wafer is coated or otherwise processed while supported on a rotary wafer support. There is a continuing drive in wafer processing applications, particularly in semiconductor wafer processing applications, to increase processing uniformity and accuracy. Accordingly, there is a continuing need for improved wafer processing schemes.

### SUMMARY OF THE INVENTION

This need is met by the present invention wherein specialized temperature control elements, spindle assemblies, and wafer processing assemblies are provided to improve wafer processing uniformity and accuracy. In accordance with one embodiment of the present invention, a heat regulating element is provided comprising a regulating element frame defining a fluid inlet and a fluid outlet; and a fluid conduit extending from the fluid inlet to the fluid outlet. The fluid conduit defines a substantially cylindrical heat regulation void. The heat regulation void defines an inside diameter selected to accommodate an object subject to heat regulation by the heat regulating element and a circumferential gas flow path between the object and the fluid conduit.

In accordance with another embodiment of the present invention, a rotary spindle assembly is provided comprising a rotary drive motor, a rotary spindle coupled to the rotary drive motor and a heat regulating element. The heat regulating element comprises a regulating element frame defining a fluid inlet and a fluid outlet and a fluid conduit extending from the fluid inlet to the fluid outlet. The fluid conduit defines a substantially cylindrical heat regulation void. The heat regulation void defines an inside diameter selected to accommodate an outside diameter of the rotary spindle and a circumferential gas flow path between the rotary spindle and the fluid conduit.

In accordance with yet another embodiment of the present invention, a rotary spindle assembly is provided comprising a rotary drive motor, a rotary spindle coupled to the rotary drive motor, a heat regulating element, a liquid source, a temperature sensor, and a controller. The heat regulating element is arranged about the rotary spindle and comprises a regulating element frame defining a fluid inlet and a fluid outlet and a fluid conduit extending from the fluid inlet to the fluid outlet. The fluid conduit defines a substantially cylindrical heat regulation void and the heat regulation void defines an inside diameter selected to accommodate an outside diameter of the rotary spindle and a circumferential gas flow path between the rotary spindle and the fluid conduit. The liquid source is coupled to the fluid conduit and the temperature sensor is coupled to the rotary spindle assembly. The controller is coupled to the liquid source and the temperature sensor and is programmed to be responsive to a temperature signal generated by the temperature sensor.

In accordance with yet another embodiment of the present invention, a wafer processing assembly is provided comprising a rotary spindle assembly, a wafer support secured to the rotary spindle so as to be rotatable therewith, and wafer processing bowl. The rotary spindle assembly comprises a rotary drive motor, a rotary spindle coupled to the rotary drive motor, and a heat regulating element. The heat regulating element comprises a regulating element frame defining a fluid inlet, a fluid outlet, and a fluid conduit extending from the fluid inlet to the fluid outlet. The fluid conduit defines a substantially cylindrical heat regulation void, and the heat regulation void defines an inside diameter selected to accommodate an outside diameter of the rotary spindle and a circumferential gas flow path between the rotary spindle and the fluid conduit. The wafer support is secured to the rotary spindle so as to be rotatable therewith. The wafer processing bowl is arranged about the wafer support and defines an exhaust gas flow profile of the wafer processing assembly.

In accordance with yet another embodiment of the present invention, a wafer processing assembly is provided comprising a rotary spindle assembly, a liquid source, a temperature sensor, a controller, a wafer support, and a wafer processing bowl. The rotary spindle assembly comprises a rotary drive motor, a rotary spindle coupled to the rotary drive motor, and a heat regulating element arranged about the rotary spindle and comprising a regulating element frame defining a fluid inlet, a fluid outlet, and a fluid conduit extending from the fluid inlet to the fluid outlet. The fluid conduit defines a substantially cylindrical heat regulation void and the heat regulation void defines an inside diameter selected to accommodate an outside diameter of the rotary spindle and a circumferential gas flow path between the rotary spindle and the fluid conduit. The liquid source is coupled to the fluid conduit. The temperature sensor is coupled to the rotary spindle assembly. The controller is coupled to the liquid source and the temperature sensor and is programmed to be responsive to a temperature signal generated by the temperature sensor. The wafer support is secured to the rotary spindle so as to be rotatable therewith. The wafer processing bowl is arranged about the wafer support and defines an exhaust gas flow profile of the wafer processing assembly. The dimensions of the circumferential gas flow path between the rotary spindle and the fluid conduit are selected to avoid substantial degradation of the exhaust gas flow profile.

In accordance with yet another embodiment of the present invention, a method for regulating heat generated by a rotary spindle assembly is provided comprising the steps of inputting a temperature signal generated by a temperature sensor and controlling a liquid source as a function of the temperature signal. The rotary spindle assembly comprises a rotary drive motor, a rotary spindle coupled to the rotary drive motor and a heat regulating element arranged about the rotary spindle.

In accordance with yet another embodiment of the present invention, a method of processing a wafer in a wafer processing assembly is provided comprising the steps of inputting a temperature signal generated by a temperature sensor, controlling a liquid source as a function of the temperature signal, and establishing dimensions of a circumferential gas flow path between a rotary spindle and a fluid conduit to avoid substantial degradation of a wafer processing assembly exhaust gas flow profile. The wafer processing assembly comprises a rotary spindle assembly including a heat regulating element, a wafer support secured to the rotary spindle so as to be rotatable therewith, and a wafer processing bowl arranged about the wafer support and defining the exhaust gas flow profile of the wafer processing assembly.

In accordance with yet another embodiment of the present invention, a heat regulating flange is provided comprising an upper surface, a lower surface, a flange body defined between the upper surface and the lower surface, a passage extending through the flange body from the upper surface to the lower surface, a fluid inlet, a fluid outlet, a fluid duct defined in the flange body and extending from the fluid inlet to the fluid outlet, and a temperature sensor positioned in thermal communication with the flange body proximate the passage.

In accordance with yet another embodiment of the present invention, a rotary spindle assembly is provided comprising a rotary drive motor, a rotary spindle coupled to the rotary drive motor, and a heat regulating flange secured to the rotary drive motor. The flange comprises an upper surface, a lower surface, a flange body defined between the upper surface and the lower surface, a rotary spindle passage aligned about the rotary spindle and extending through the flange body from the upper surface to the lower surface, a fluid inlet, a fluid outlet, a fluid duct defined in the flange body and extending from the fluid inlet to the fluid outlet, and a temperature sensor positioned in thermal communication with the flange body proximate the rotary spindle passage.

In accordance with yet another embodiment of the present invention, a rotary spindle assembly is provided comprising a rotary drive motor, a rotary spindle coupled to the rotary drive motor, a heat regulating flange secured to the rotary drive motor, a liquid source, and a controller. The heat regulating flange is secured to the rotary drive motor and comprises an upper surface, a lower surface in contact with the rotary drive motor, a flange body defined between the upper surface and the lower surface, a rotary spindle passage aligned about the rotary spindle and extending through the flange body from the upper surface to the lower surface, a fluid inlet, a fluid outlet, a fluid duct defined in the flange body and extending from the fluid inlet to the fluid outlet, and a temperature sensor positioned in thermal communication with the flange body proximate the rotary spindle passage. The liquid source is coupled to the fluid duct. The controller is coupled to the liquid source and the temperature sensor and is programmed to be responsive to a temperature signal generated by the temperature sensor.

In accordance with yet another embodiment of the present invention, a wafer processing assembly is provided comprising a rotary spindle assembly, a wafer support, and a wafer processing bowl. The rotary spindle assembly comprises a rotary drive motor, a rotary spindle coupled to the rotary drive motor, and a heat regulating flange secured to the rotary drive motor. The flange comprises an upper surface, a lower surface, a flange body defined between the upper surface and the lower surface, a rotary spindle passage aligned about the rotary spindle and extending through the flange body from the upper surface to the lower surface, a fluid inlet, a fluid outlet, a fluid duct defined in the flange body and extending from the fluid inlet to the fluid outlet, and a temperature sensor positioned in thermal communication with the flange body proximate the rotary spindle passage. The wafer support is secured to the rotary spindle so as to be rotatable therewith. The wafer processing bowl is arranged about the wafer support and defines an exhaust gas flow profile of the wafer processing assembly.

In accordance with yet another embodiment of the present invention, a wafer processing assembly is provided comprising a rotary spindle assembly, a liquid source, a controller, a wafer support, and a wafer processing bowl. The rotary spindle assembly comprises a rotary drive motor, a rotary spindle coupled to the rotary drive motor, and a heat regulating flange secured to the rotary drive motor. The flange comprises an upper surface, a lower surface in contact with the rotary drive motor, a flange body defined between the upper surface and the lower surface, a rotary spindle passage aligned about the rotary spindle and extending through the flange body from the upper surface to the lower surface, a fluid inlet, a fluid outlet, a fluid duct defined in the flange body and extending from the fluid inlet to the fluid outlet, and a temperature sensor positioned in thermal communication with the flange body proximate the rotary spindle passage. The liquid source is coupled to the fluid duct. The controller is coupled to the liquid source and the temperature sensor and is programmed to be responsive to a temperature signal generated by the temperature sensor. The wafer support is secured to the rotary spindle so as to be rotatable therewith. The wafer processing bowl is arranged about the wafer support and defines an exhaust gas flow profile of the wafer processing assembly.

In accordance with yet another embodiment of the present invention, a method for regulating heat generated by a rotary spindle assembly is provided comprising the steps of inputting a temperature signal generated by a temperature sensor and controlling a liquid source as a function of the temperature signal. The rotary spindle assembly comprises a rotary drive motor, a rotary spindle coupled to the rotary drive motor, and a heat regulating flange secured to the rotary drive motor.

In accordance with yet another embodiment of the present invention, a method of processing a wafer in a wafer processing assembly is provided comprising the steps of inputting a temperature signal generated by a temperature sensor and controlling a liquid source as a function of the temperature signal. The wafer processing assembly comprises a rotary spindle assembly, a wafer support secured to the rotary spindle so as to be rotatable therewith, and a wafer processing bowl arranged about the wafer support, the wafer processing bowl defining an exhaust gas flow profile of the wafer processing assembly. The rotary spindle assembly comprises a rotary drive motor, a rotary spindle coupled to the rotary drive motor, and a heat regulating flange secured to the rotary drive motor.

In accordance with yet another embodiment of the present invention a rotary spindle assembly is provided comprising a rotary drive motor, a rotary spindle coupled to the rotary drive motor, a heat regulating element, and a heat regulating flange secured to the rotary drive motor.

In accordance with yet another embodiment of the present invention, a wafer processing assembly is provided comprising a rotary spindle assembly, a wafer support, and a wafer processing bowl. The rotary spindle assembly comprises a rotary drive motor, a rotary spindle coupled to the rotary drive motor, a heat regulating element, and a heat regulating flange secured to the rotary drive motor. The wafer support is secured to the rotary spindle so as to be rotatable therewith. The wafer processing bowl is arranged about the wafer support and defines an exhaust gas flow profile of the wafer processing assembly.

Accordingly, it is an object of the present invention to provide improved heat regulation elements, spindle assemblies, and wafer processing assemblies. Other objects of the present invention will be apparent in light of the description of the invention embodied herein.

### BRIEF DESCRIPTION OF THE SEVERAL VIEWS OF THE DRAWINGS

The following detailed description of the preferred embodiments of the present invention can be best understood when read in conjunction with the following drawings, where like structure is indicated with like reference numerals and in which:

FIG. 1 is a schematic illustration of a wafer processing assembly incorporating a heat regulating flange according to one embodiment of the present invention;

FIG. 2 is a schematic illustration of a wafer processing assembly incorporating a wafer backside heat regulating element according to one embodiment of the present invention;

FIG. 3 is a detailed three dimensional illustration of a heat regulating flange according to one embodiment of the present invention; and

FIG. 4 is a detailed three dimensional illustration of a wafer backside heat regulating element according to one embodiment of the present invention.

### DETAILED DESCRIPTION

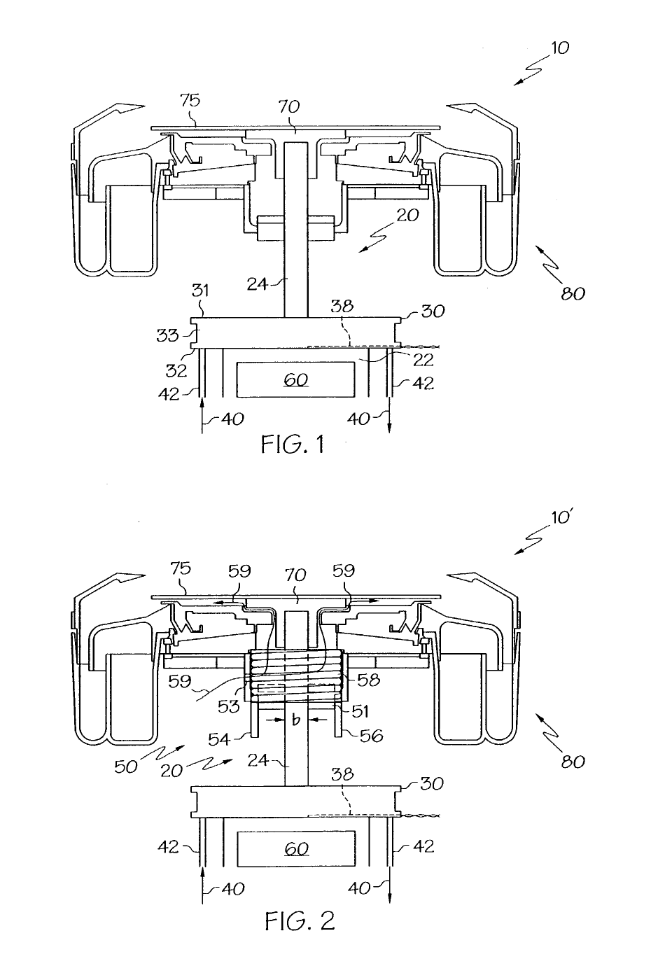

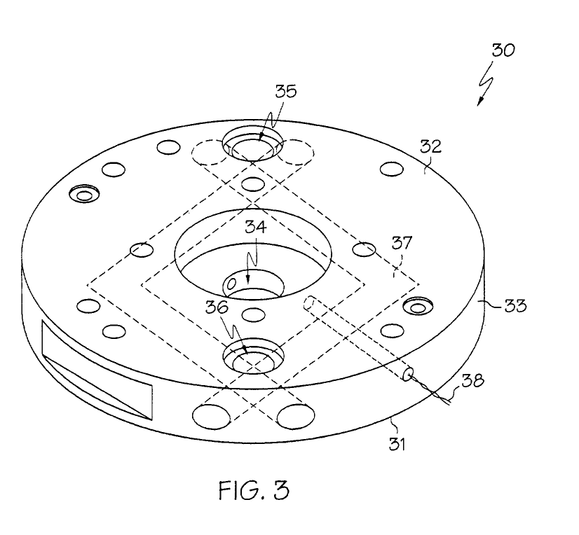

Referring initially to FIGS. 1 and 3, a wafer processing assembly 10 according to one embodiment of the present invention is illustrated. The wafer processing assembly 10 comprises a rotary spindle assembly 20, a heat regulating flange 30, a liquid source (illustrated schematically by arrow 40), a controller 60, a wafer support 70, and a wafer processing bowl 80. The rotary spindle assembly 20 comprises a rotary drive motor 22, a rotary spindle 24 coupled to the rotary drive motor 22 and the heat regulating flange 30. A wafer 75 is illustrated in a secured state, supported by the wafer support 70. For the purposes of describing and defining the present invention, it is noted that a flange comprises and piece of hardware or hardware assembly that is arranged to be mounted to an adjacent piece of hardware or hardware assembly. The controller 60 is merely illustrated schematically and is typically merely coupled to the remainder of the assembly 10 via an electronic data connection. As is described in further detail herein, the controller 60 may comprise a control unit programmed to control motor speed and to monitor and control the temperature of various parts of the assembly 10.

The heat regulating flange 30 is secured to the rotary drive motor 22 so as to be thermally coupled thereto. The flange 30 comprises an upper surface 31, a lower surface 32 in contact with the rotary drive motor 22, and a flange body 33 defined between the upper surface 31 and the lower surface 32. A rotary spindle passage 34 is aligned about the rotary spindle 24 and extends through the flange body 33 from the upper surface 31 to the lower surface 32. A fluid inlet 35, a fluid outlet 36, and a fluid duct 37 are defined in the flange body 33. Respective input and output feed pipes 42 are provided in communication with the fluid inlet 35 and fluid outlet 36.

Referring specifically to FIG. 3, the fluid duct 37 may be defined by machining bores in the flange body 33. The bores are arranged such that respective perpendicular bores defining the fluid inlet 35 and the fluid outlet 36 will communicate with the bores of the fluid duct 37. The fluid duct 37 preferably defines a closed flow path extending from the fluid inlet 35 to the fluid outlet 36. Accordingly, in the embodiment illustrated in FIG. 3, the ends of the fluid duct 37 open to the ambient on the periphery of the flange body 33 are preferably plugged. In this manner, the fluid duct 37 extends from the fluid inlet 35 to the fluid outlet 36 and is preferably arranged about the rotary spindle passage 34 to provide uniform regulation of the temperature of the flange body 33 relative to the passage 34. It is contemplated by the present invention, however, that the fluid duct 37 need not surround or be symmetrical with respect to the passage 34.

A temperature sensor 38 is positioned in thermal communication with the flange body 33 proximate the rotary spindle passage 34, preferably by embedding the temperature sensor 38 in the flange body 33 on the side of the flange body 33 directly opposite the rotary drive motor 22. It is contemplated by the present invention, however, that the temperature sensor may be placed in any position suitable for providing a signal indicative of the temperature of the rotary drive motor 22 and the flange body 33, including positions remote from but in thermal communication with the flange body 33.

In operation, the controller 60 is coupled to the liquid source 40 and the temperature sensor 38 and is programmed to be responsive to a temperature signal generated by the temperature sensor 38. More specifically, the temperature sensor 38 provides temperature feedback from the flange body 33 to the controller 60 and may comprise a resistive thermal device, a thermocouple sensor, or any other sensor suitable to provide temperature feedback to the controller 60. The controller 60 responds to the feedback signal by controlling the liquid supply to the fluid duct 37 so as to increase or decrease the temperature of the flange body 33 to bring it in line with a target flange body temperature. Temperature regulation may be achieved by altering the fluid flow rate through the fluid duct 37 or by altering the temperature of the fluid in the fluid duct 37.

Referring specifically to FIG. 3, it is noted that the temperature sensor 38 may alternatively be provided in a bore 39 formed just below the lower surface 32 of the flange body 33, as opposed to formation in a channel, as is illustrated in FIGS. 1 and 2. In either case, it is often preferable to form the channel or bore as close as possible to the lower surface 32 and to back fill the channel or bore with a conventional RTV composition.

The wafer support 70 is secured to the rotary spindle 24 so as to be rotatable therewith. The wafer processing bowl 80 is arranged about the wafer support 70 and defines an exhaust gas flow profile of the wafer processing assembly 10. The specific arrangements of the wafer support 70 and the wafer processing bowl 80 are beyond the scope of the present invention and may be gleaned from conventional wafer processing technology. For example, U.S. Pat. No. 5,705,223, the disclosure of which is incorporated herein by reference, illustrates a suitable wafer support and bowl arrangement.

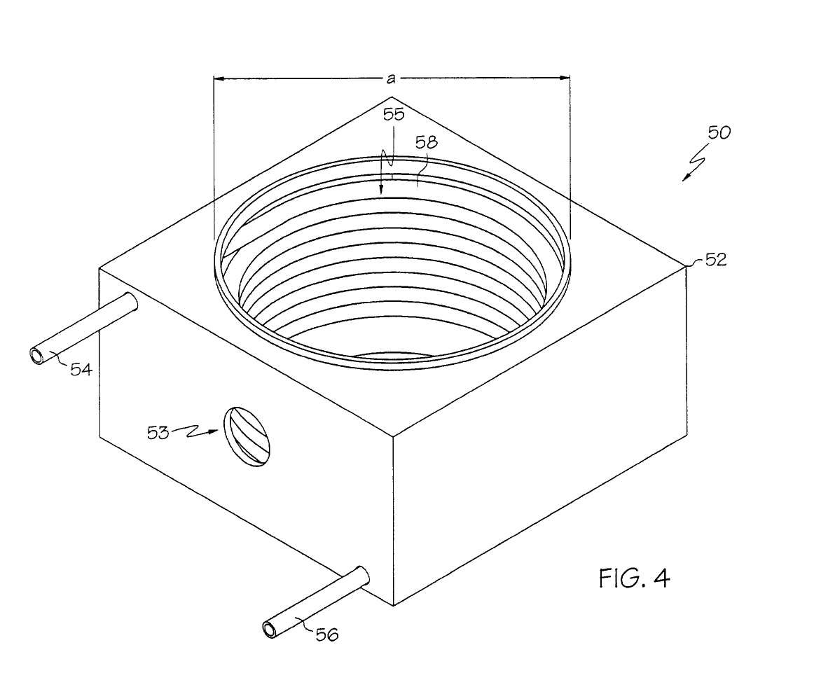

Referring now to FIGS. 2 and 4, a wafer processing assembly 10′ including a heat regulating flange 30 and a wafer backside heat regulating element 50 according to the present invention is illustrated. The heat regulating element 50 is arranged about the rotary spindle 24 and comprises a regulating element frame 52 defining a fluid inlet 54, a fluid outlet 56, and a fluid conduit 58 extending from the fluid inlet 54 to the fluid outlet 56. The fluid conduit 58 defines a substantially cylindrical heat regulation void 55 and the heat regulation void 55 defines an inside diameter a. The inside diameter a is selected to accommodate an outside diameter b of the rotary spindle 24 and a circumferential gas flow path 59 between the rotary spindle 24 and the fluid conduit 58. The dimensions of the circumferential gas flow path 59 between the rotary spindle 24 and the fluid conduit 58 are established to ensure sufficient heat regulation and to avoid substantial degradation of the exhaust gas flow profile defined by the wafer processing bowl 80. For example, if the spacing between the rotary spindle 24 and the fluid conduit 58 is too large temperature control will be compromised and excess gas flow moving between the rotary spindle 24 and the fluid conduit 58 will interrupt or degrade the exhaust of gasses from the interior of the bowl 80 and cause wafer contamination.

For the purposes of describing and defining the present invention, it is noted that a spindle comprises a shaft or other cylindrical or non-cylindrical rotary drive element, the outside diameter of which is defined by its rotating cross-section. It is also noted that heat regulating element 50 may be employed anywhere along the spindle 24 and is identified herein as a wafer backside heat regulating element merely to help describe its general location relative to the wafer support 70.

It is noted that the circumferential gas flow path 59 and the heat regulation void 55 are substantially cylindrical but will vary from a perfect cylinder because of the presence of non-cylindrical irregularities in the flow path 59 and void 55. For example, where the fluid conduit 58 comprises a length of spirally wound tubing, the gas flow path 59 and void 55 would be defined by the profiles of the adjacent windings of the tubing and would not define a perfect cylinder. It is also noted that the fluid inlet 54 and fluid outlet 56 of the heat regulating element frame 52 may define portion of fluid conduit itself or may merely define a passage that accommodates a tube or other fluid conduit.

In the illustrated embodiment, the regulating element frame 52 comprises a body including a cylindrical cut-out and the fluid conduit 58 comprises a length of tubing arranged about the periphery of the cylindrical cut-out. The tubing may comprise conventional PVC tubing, stainless steel tubing, or other suitable tubing material. It is contemplated by the present invention that the fluid conduit may be provided in a variety of forms other than tubing. For example, the fluid conduit may comprise a single wide passage arranged about the periphery of the cut-out.

In the illustrated embodiment, the heat regulating element frame 52 is supported by a ring chuck 51 and further defines at least one gas intake port 53 in communication with the circumferential gas flow path 59. Gas will typically also be provided in communication with the circumferential gas flow path 59 via gaps between the heat regulating element frame 52, the ring chuck 51, and the rotary spindle 24. Indeed, in some applications of the present invention, the gas intake port 53 may not be necessary to support the desired amount of flow volume in the circumferential gas flow path 59. Alternatively, a plurality of gas intake ports 54 may be necessary. The gas may comprise air from the ambient or may be supplied by a compressed or ambient supply of inert gas.

The controller 60 may be arranged to monitor the temperature of the fluid in the fluid conduit 58 to provide an additional temperature feedback signal. In which case, it may be preferable to provide an independent fluid supply for communication with the fluid conduit 58 of the regulating element frame 52 and to control the independent fluid supply in response to the temperature feedback signal.

In operation, wafer backside heat regulating element and the heat regulating flange are utilized to stabilize the temperature of the various components of the wafer processing assembly 10, 10′ and to make more uniform the temperature profile of a wafer subject to processing thereby. Temperature regulation is achieved by controlling the fluid supply to heat regulating flange 30, the heat regulating element 50, or both. For example, the controller may be programmed to alter a rate of flow of fluid through the fluid duct 37, the fluid conduit 58, or both, or may be programmed to alter the temperature of fluid in the fluid duct 37, the fluid conduit 58, or both, in response to a temperature signal generated by the temperature sensor. The present invention may incorporate a single liquid source coupled to the fluid conduit and the fluid duct or individual liquid sources coupled independently to the fluid conduit and the fluid duct.

Having described the invention in detail and by reference to preferred embodiments thereof, it will be apparent that modifications and variations are possible without departing from the scope of the invention defined in the appended claims.

What is claimed is:

1. A method for regulating heat generated by a rotary spindle assembly comprising inputting a temperature signal generated by a temperature sensor and controlling a liquid source as a function of said temperature signal, wherein said rotary spindle assembly comprises:
a rotary drive motor;
a rotary spindle coupled to said rotary drive motor;
a heat regulating element arranged about said rotary spindle and comprising
a regulating element frame defining a fluid inlet and a fluid outlet; and
a fluid conduit extending from said fluid inlet to said fluid outlet, wherein
said fluid conduit defines a substantially cylindrical heat regulation void, and
said heat regulation void defines an inside diameter selected to accommodate an outside diameter of said rotary spindle and a circumferential gas flow path between said rotary spindle and said fluid conduit, wherein said liquid source is coupled to said fluid conduit, said temperature sensor is coupled to said rotary spindle assembly.

2. A method of processing a wafer in a wafer processing assembly comprising inputting a temperature signal generated by a temperature sensor, controlling a liquid source as a function of said temperature signal, and establishing dimensions of a circumferential gas flow path between a rotary spindle and a fluid conduit to avoid substantial degradation of an exhaust gas flow profile, wherein said wafer processing assembly comprises:
a rotary spindle assembly comprising
a rotary drive motor,
said rotary spindle coupled to said rotary drive motor, and
a heat regulating element arranged about said rotary spindle and comprising a regulating element frame defining a fluid inlet, a fluid outlet, and said fluid conduit extending from said fluid inlet to said fluid outlet, wherein said fluid conduit defines a substantially cylindrical heat regulation void, and said heat regulation void defines an inside diameter selected to accommodate an outside diameter of said rotary spindle and said circumferential gas flow path between said rotary spindle and said fluid conduit, wherein said liquid source is coupled to said fluid conduit and said temperature sensor is coupled to said rotary spindle assembly;
a wafer support secured to said rotary spindle so as to be rotatable therewith; and
a wafer processing bowl arranged about said wafer support, said wafer processing bowl defining said exhaust gas flow profile of said wafer processing assembly.

3. A method for regulating heat generated by a rotary spindle assembly comprising inputting a temperature signal generated by a temperature sensor and controlling a liquid source as a function of said temperature signal, wherein said rotary spindle assembly comprises:
a rotary drive motor;
a rotary spindle coupled to said rotary drive motor; and
a heat regulating flange secured to said rotary drive motor, said flange comprising
an upper surface,
a lower surface in contact with said rotary drive motor,
a flange body defined between said upper surface and said lower surface,
a rotary spindle passage aligned about said rotary spindle and extending through said flange body from said upper surface to said lower surface,
a fluid inlet,
a fluid outlet,
a fluid duct defined in said flange body and extending from said fluid inlet to said fluid outlet, and
said temperature sensor is positioned in thermal communication with said flange body proximate said rotary spindle passage, wherein said liquid source is coupled to said fluid duct.

4. A method of processing a wafer in a wafer processing assembly comprising inputting a temperature signal generated by a temperature sensor and controlling a liquid source as a function of said temperature signal, wherein said wafer processing assembly comprises:
a rotary spindle assembly comprising
a rotary drive motor;
a rotary spindle coupled to said rotary drive motor; and
a heat regulating flange secured to said rotary drive motor, said flange comprising an upper surface, a lower surface in contact with said rotary drive motor, a flange body defined between said upper surface and said lower surface, a rotary spindle passage aligned about said rotary spindle and extending through said flange body from said upper surface to said lower surface, a fluid inlet, a fluid outlet, a fluid duct defined in said flange body and extending from said fluid inlet to said fluid outlet, and said temperature sensor positioned in thermal communication with said flange body proximate said rotary spindle passage, wherein said liquid source is coupled to said fluid duct;
a wafer support secured to said rotary spindle so as to be rotatable therewith; and
a wafer processing bowl arranged about said wafer support, said wafer processing bowl defining an exhaust gas flow profile of said wafer processing assembly.

5. A method for regulating heat generated by a rotary spindle assembly comprising inputting a temperature signal generated by a temperature sensor and controlling at least one liquid source as a function of said temperature signal, wherein said rotary spindle assembly comprises:
a rotary drive motor;
a rotary spindle coupled to said rotary drive motor;
a heat regulating element arranged about said rotary spindle and comprising
a regulating element frame defining a fluid inlet and a fluid outlet; and
a fluid conduit extending from said fluid inlet to said fluid outlet, wherein
said fluid conduit defines a substantially cylindrical heat regulation void, and
said heat regulation void defines an inside diameter selected to accommodate an outside diameter of said rotary spindle and a circumferential gas flow path between said rotary spindle and said fluid conduit, wherein said liquid source is coupled to said fluid conduit; and
a heat regulating flange secured to said rotary drive motor, said flange comprising
an upper surface,
a lower surface in contact with said rotary drive motor,
a flange body defined between said upper surface and said lower surface,
a rotary spindle passage aligned about said rotary spindle and extending through said flange body from said upper surface to said lower surface,
a fluid inlet,
a fluid outlet,
a fluid duct defined in said flange body and extending from said fluid inlet to said fluid outlet, and
said temperature sensor is positioned in thermal communication with said flange body proximate said rotary spindle passage, wherein said liquid source is coupled to said fluid duct.

6. A method of processing a wafer in a wafer processing assembly comprising inputting a temperature signal generated by a temperature sensor, controlling at least one liquid source as a function of said temperature signal, and establishing dimensions of a circumferential gas flow path between a rotary spindle and a fluid conduit to avoid substantial degradation of an exhaust gas flow profile, wherein said wafer processing assembly comprises:
a rotary spindle assembly comprising
a rotary drive motor,
said rotary spindle coupled to said rotary drive motor, and
a heat regulating element arranged about said rotary spindle and comprising a regulating element frame defining a fluid inlet, a fluid outlet, and said fluid conduit extending from said fluid inlet to said fluid outlet, wherein said fluid conduit defines a substantially cylindrical heat regulation void, and said heat regulation void defines an inside diameter selected to accommodate an outside diameter of said rotary spindle and said circumferential gas flow path between said rotary spindle and said fluid conduit, wherein said liquid source is coupled to said fluid conduit;
a heat regulating flange secured to said rotary drive motor, said flange comprising an upper surface, a lower surface in contact with said rotary drive motor, a flange body defined between said upper surface and said lower surface, a rotary spindle passage aligned about said rotary spindle and extending through said flange body from said upper surface to said lower surface, a fluid inlet, a fluid outlet, a fluid duct defined in said flange body and extending from said fluid inlet to said fluid outlet, and said temperature sensor positioned in thermal communication with said flange body proximate said rotary spindle passage, wherein said liquid source is coupled to said fluid duct;
a wafer support secured to said rotary spindle so as to be rotatable therewith; and
a wafer processing bowl arranged about said wafer support, said wafer processing bowl defining said exhaust gas flow profile of said wafer processing assembly.

7. The method as claimed in claim 1 wherein said regulating element frame further defines at least one gas intake port, and wherein said gas intake port is in communication with said circumferential gas flow path.

8. The method as claimed in claim 1 wherein said regulating element frame comprises a body including a cylindrical cut-out, and wherein said fluid conduit is arranged about the periphery of said cylindrical cut-out.

9. The method as claimed in claim 1 wherein said fluid conduit comprises a length of tubing.

10. The method as claimed in claim 9 wherein said length of tubing is wound to define said substantially cylindrical heat regulation void.

11. The method assembly as claimed in claim 1 wherein said rotary spindle comprises a cylindrical shaft.

12. The method as claimed in claim 1 wherein said rotary spindle assembly further comprises a ring chuck arranged to support said heat regulating element.

13. The method as claimed in claim 1 wherein said temperature sensor is positioned in said circumferential gas flow path.

14. The method as claimed in claim 1 wherein said temperature sensor is positioned to measure a temperature of liquid in said fluid conduit.

15. The method as claimed in claim 1 wherein said step of controlling a liquid source as a function of said temperature signal comprises altering a rate of flow of fluid through said fluid conduit in response to said temperature signal generated by said temperature sensor.

16. The method as claimed in claim 1 wherein said step of controlling a liquid source as a function of said temperature signal comprises altering a temperature of fluid in said fluid conduit in response to said temperature signal generated by said temperature sensor.

17. The method as claimed in claim 3 wherein said temperature sensor is embedded in said flange body.

18. The method as claimed in claim 3 wherein said fluid duct is arranged about said passage.

19. The method as claimed in claim 5 wherein said at least one liquid source comprises a single liquid source coupled to said fluid conduit and said fluid duct.

20. The method as claimed in claim 5 wherein said at least one liquid source comprises a first liquid source coupled to said fluid conduit and a second liquid source coupled to said fluid duct.

21. The method as claimed in claim 5 wherein said heat regulating element further comprises an additional temperature sensor coupled to said rotary spindle assembly, wherein said controller is coupled to said additional temperature sensor and is programmed to be responsive to a temperature signal generated by said additional temperature sensor.
